(19) United States
(12) Patent Application Publication
(10) Pub. No.: US 2026/0334012 A1
(43) Pub. Date: Oct. 22, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: Changsuk LEE, Yongin-si (KR); Daewon CHOI, Yongin-si (KR)

(73) Assignee: Samsung Display Co., Ltd., Yongin-si (KR)

(21) Appl. No.: 19/443,249

(22) Filed: Jan. 8, 2026

(30) Foreign Application Priority Data
Apr. 17, 2025 (KR) 10-2025-0050313

(51) Int. Cl. H10K 59/122; H10K 59/12; H10K 59/88

(52) U.S. Cl. CPC H10K 59/122; H10K 59/1201; H10K 59/88

(57) ABSTRACT

A display device may include: a substrate; a first electrode on the substrate; a pixel defining layer on the first electrode and including: a pixel opening exposing a central portion of the first electrode, a spacer portion at an outer side of the first electrode, the spacer portion protruding in an upward direction; and a recessed portion between the spacer portion and the pixel opening, the recessed portion being recessed in a downward direction; a metal layer on the pixel defining layer and including a tip, the tip overlapping with the pixel opening in the upward direction, and defining a light-emitting area; a light-emitting layer on the first electrode; and a second electrode on the light-emitting layer, in the pixel opening, the second electrode being connected to the tip of the metal layer.

### CROSS-REFERENCE TO RELATED APPLICATION

The present application claims priority to Korean Patent Application No. 10-2025-0050313, filed on Apr. 17, 2025, in the Korean Intellectual Property Office, the disclosure of which is incorporated herein by reference in its entirety.

### BACKGROUND

### FIELD

Some embodiments of the present disclosure relate to a display device, a method of manufacturing the display device, and an electronic device including the display device. More specifically, some embodiments of the present disclosure relate to a display device which provides visual information, a method of manufacturing the display device, and an electronic device including the display device.

### DESCRIPTION OF BACKGROUND ART

A light-emitting layer included in a display device may include common layers which are commonly provided to a plurality of light-emitting elements. The common layers may include a hole injection layer, a hole transport layer, an electron transport layer, and an electron injection layer. Accordingly, in case that current is supplied to one light-emitting element, current may also be supplied to adjacent light-emitting elements through the common layers commonly provided for the plurality of light-emitting elements, thereby causing a problem of deteriorated color purity of the display device. To address this problem, the display device may include a separator for disconnecting the common layers.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a display device with a simplified manufacturing process may be provided.

According to some embodiments of the present disclosure, a method of manufacturing the display device may be provided.

According to some embodiments of the present disclosure, an electronic device including the display device may be provided.

According to some embodiments of the present disclosure, a display device may include: a substrate; a first electrode on the substrate; a pixel defining layer on the first electrode and including: a pixel opening exposing a central portion of the first electrode, a spacer portion at an outer side of the first electrode, the spacer portion protruding in an upward direction; and a recessed portion between the spacer portion and the pixel opening, the recessed portion being recessed in a downward direction; a metal layer on the pixel defining layer and including a tip, the tip overlapping with the pixel opening in the upward direction, and defining a light-emitting area; a light-emitting layer on the first electrode; and a second electrode on the light-emitting layer, in the pixel opening, wherein the second electrode is connected to the tip of the metal layer.

According to some embodiments of the present disclosure, the tip overlaps with the light-emitting layer in the upward direction.

According to some embodiments of the present disclosure, an upper portion of the spacer portion is exposed from the metal layer.

According to some embodiments of the present disclosure, a thickness of the metal layer is less than 1000 Å.

According to some embodiments of the present disclosure, the metal layer includes only a single layer, the single layer including titanium.

According to some embodiments of the present disclosure, the metal layer includes a first layer including titanium, and a second layer including aluminum.

According to some embodiments of the present disclosure, the display device further includes: a first dummy layer on the pixel defining layer, wherein a material of the first dummy layer is the same as a material of the light-emitting layer; and a second dummy layer on the first dummy layer, wherein a material of the second dummy layer is the same as a material of the second electrode.

According to some embodiments of the present disclosure, the first dummy layer is spaced apart from the light-emitting layer.

According to some embodiments of the present disclosure, the second dummy layer is spaced apart from the second electrode.

According to some embodiments of the present disclosure, a method of manufacturing a display device may include: forming a first electrode on a substrate; forming a pixel defining layer on the first electrode, the pixel defining layer including: a spacer portion at an outer side of the first electrode, the spacer portion protruding in an upward direction; and a recessed portion between the spacer portion and the first electrode, the recessed portion being recessed in a downward direction; forming a preliminary metal layer on the pixel defining layer; forming, by removing a portion of the pixel defining layer, a pixel opening that exposes a central portion of the first electrode; forming a metal layer by removing a portion of the preliminary metal layer, wherein the metal layer includes a tip that overlaps with the pixel opening in the upward direction and defines a light-emitting area; forming a light-emitting layer on the first electrode; and forming a second electrode on the light-emitting layer, in the pixel opening, wherein the second electrode is connected to the tip of the metal layer.

According to some embodiments of the present disclosure, the forming the pixel defining layer includes forming the pixel defining layer by using a halftone mask.

According to some embodiments of the present disclosure, the metal layer includes: only a single layer, the single layer including titanium; or a first layer including titanium, and a second layer including aluminum.

According to some embodiments of the present disclosure, the forming the metal layer includes: forming a photoresist pattern on the preliminary metal layer; forming an opening, overlapping with the first electrode in the upward direction, by removing a portion of the preliminary metal layer exposed from the photoresist pattern; exposing, by removing a portion of the photoresist pattern, a first portion of the preliminary metal layer in contact with the spacer portion and a second portion of the preliminary metal layer adjacent to the opening; removing the first portion and the second portion of the preliminary metal layer; and removing a remainder of the photoresist pattern, and wherein the forming the pixel opening is performed simultaneously with the removing the portion of the photoresist pattern.

According to some embodiments of the present disclosure, after the forming the pixel opening, the preliminary metal layer includes the second portion and a preliminary tip, the preliminary tip defining the opening.

According to some embodiments of the present disclosure, the removing the first portion and the second portion of the preliminary metal layer includes expanding a size of the pixel opening so that at least a portion of the first electrode is exposed.

According to some embodiments of the present disclosure, after the forming the photoresist pattern, a height from an upper surface of the first portion of the preliminary metal layer to an upper surface of the photoresist pattern is less than a height from an upper surface of the first electrode to an upper surface of the pixel defining layer.

According to some embodiments of the present disclosure, after the forming the opening, a width of the opening is less than a width of the first electrode.

According to some embodiments of the present disclosure, an electronic device may include the display device and at least one processor configured to control the display device.

According to some embodiments of the present disclosure, an upper portion of the spacer portion is exposed from the metal layer, and the tip overlaps with the light-emitting layer in the upward direction.

According to some embodiments of the present disclosure, a thickness of the metal layer is less than about 1000 Å.

The display device according to some embodiments of the present disclosure may include a pixel defining layer disposed on a first electrode, the pixel defining layer having a spacer portion protruding upward at an outer side the first electrode, and a recessed portion recessed downward between the spacer portion and a pixel opening, and a metal layer on the pixel defining layer and having a tip defining an undercut shape, together with the pixel opening. As a result, a light-emitting layer may be formed to be separated by the tip. Accordingly, even if current is supplied to the light-emitting layer, current may not be supplied to an adjacent light-emitting layer. As a result, leakage current may be reduced, and the color purity of the display device may be improved. In addition, the manufacturing process may be simplified to improve productivity and reduce process costs.

### BRIEF DESCRIPTION OF DRAWINGS

Non-limiting example embodiments of the present disclosure will be more clearly understood from the following detailed description in conjunction with the accompanying drawings.

FIG. 1 is a plan view illustrating a display device according to an embodiment of the present disclosure.

FIG. 2 is an enlarged plan view of an area A in FIG. 1.

FIG. 3 is a cross-sectional view taken along a line I-I’ of FIG. 2 according to an embodiment.

FIGS. 4-15 are cross-sectional views for illustrating a method of manufacturing the display device of FIG. 3.

FIG. 16 is a schematic block diagram of an electronic device according to an embodiment of the present disclosure.

FIG. 17 is a schematic diagram of various electronic devices according to various embodiments.

### DETAILED DESCRIPTION

Hereinafter, non-limiting example embodiments of the present disclosure will be described in more detail with reference to the accompanying drawings. In the drawings, the same reference numerals and characters are used for the same components in the drawings, and redundant descriptions of the same components may not be provided for conciseness.

In this specification, a plane may be defined by a first direction DR1 and a second direction DR2 which intersects the first direction DR1. For example, the second direction DR2 may be perpendicular to the first direction DR1. In addition, a third direction DR3 (e.g., an upward direction) may be a normal direction of the plane. That is, the third direction DR3 may be perpendicular to the plane defined by the first direction DR1 and the second direction DR2.

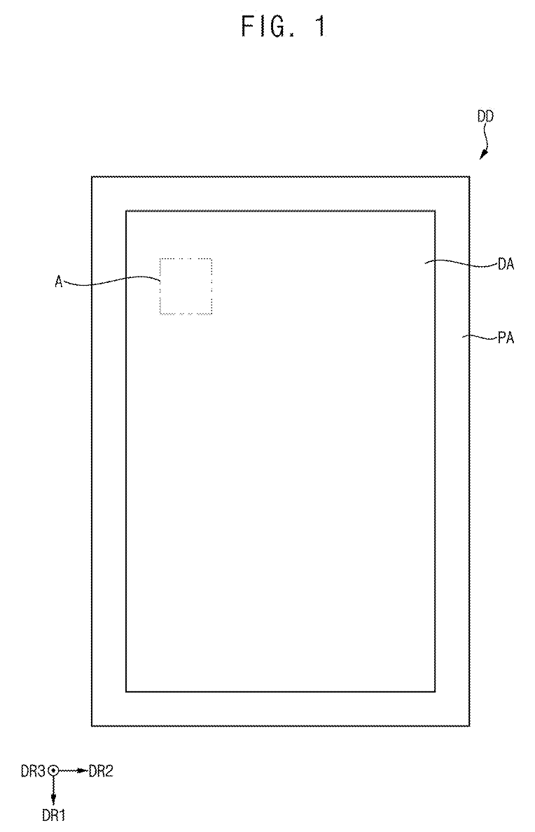

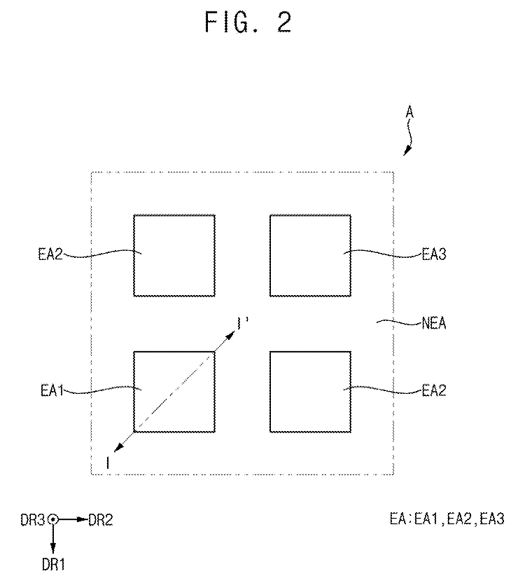

FIG. 1 is a plan view illustrating a display device according to an embodiment of the present disclosure. FIG. 2 is an enlarged plan view of an area A in FIG. 1.

Referring to FIGS. 1 and 2, a display device DD may include a display area DA and a peripheral area PA. The display area DA may be an area which generates light or controls the transmittance of light provided from an external light source to display an image. The peripheral area PA may be located around the display area DA. For example, in a plan view, the peripheral area PA may surround at least a portion of the display area DA. In an embodiment, the peripheral area PA may be an area which does not display an image. However, embodiments of the present disclosure are not limited thereto. For example, the image may also be displayed in at least a portion of the peripheral area PA.

The display area DA may include light-emitting areas EA and a non-light-emitting area NEA. The light-emitting areas EA may include a first light-emitting area EA1, a second light-emitting area EA2, and a third light-emitting area EA3. Each of the first light-emitting area EA1, the second light-emitting area EA2, and the third light-emitting area EA3 may be an area in which light emitted from a light-emitting element LED is emitted to an outside of the display device DD. For example, the first light-emitting area EA1 may emit red light, the second light-emitting area EA2 may emit green light, and the third light-emitting area EA3 may emit blue light. However, embodiments of the present disclosure are not limited thereto. For example, the light-emitting areas EA may also be combined to emit yellow, cyan, and crimson light.

In a plan view, each of the first light-emitting area EA1, the second light-emitting area EA2, and the third light-emitting area EA3 may be repeatedly arranged along the first direction D1 and the second direction D2.

Each of the first light-emitting area EA1, the second light-emitting area EA2, and the third light-emitting area EA3 may have the same size. However, embodiments of the present disclosure are not limited thereto. For example, the first light-emitting area EA1, the second light-emitting area EA2, and the third light-emitting area EA3 may have different sizes from each other.

For example, each of the first light-emitting area EA1, the second light-emitting area EA2, and the third light-emitting area EA3 may have a triangular planar shape, a quadrilateral planar shape, a circular planar shape, an elliptical planar shape, or the like. In an embodiment, each of the first light-emitting area EA1, the second light-emitting area EA2, and the third light-emitting area EA3 may have the quadrilateral planar shape. However, embodiments of the present disclosure are not limited thereto.

The non-light-emitting area NEA may surround the first light-emitting area EA1, the second light-emitting area EA2, and the third light-emitting area EA3 in a plan view. For example, the non-light-emitting area NEA may have a grid shape in the plan view. The non-light-emitting area NEA may not emit light.

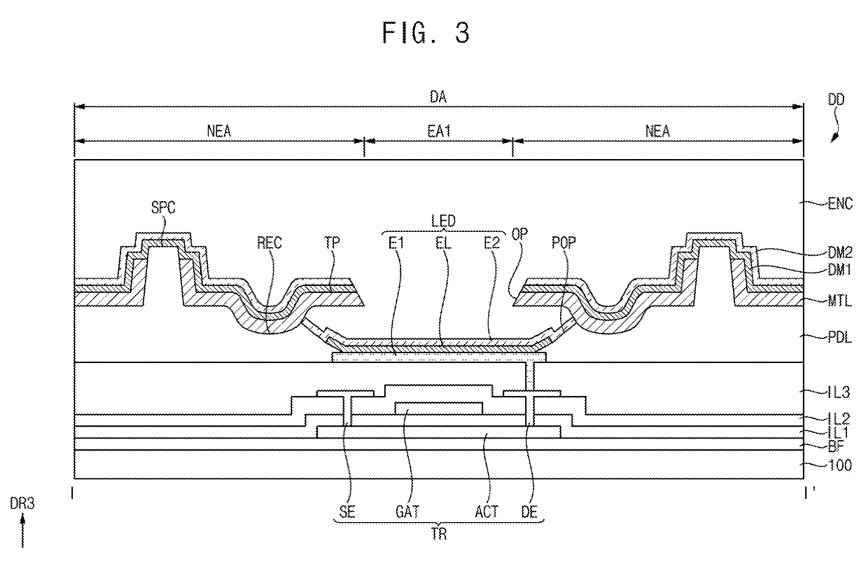

FIG. 3 is a cross-sectional view taken along a line I-I’ of FIG. 2 according to an embodiment. Specifically, FIG. 3 is a cross-sectional view of the first light-emitting area EA1 of FIG. 2, and the cross-sectional views of the second light-emitting area EA2 and the third light-emitting area EA3 of FIG. 2 may be substantially the same as the cross-sectional view of the first light-emitting area EA1.

Referring to FIG. 3, the display device DD according to an embodiment of the present disclosure may include a substrate 100, a buffer layer BF, a first insulating layer IL1, a second insulating layer IL2, a third insulating layer IL3, a transistor TR, a pixel defining layer PDL, a light-emitting element LED, a metal layer MTL, a first dummy layer DM1, a second dummy layer DM2, and a encapsulation layer ENC.

The transistor TR may include an active pattern ACT, a gate electrode GAT, a source electrode SE, and a drain electrode DE. The light-emitting element LED may include a first electrode E1, a light-emitting layer EL, and a second electrode E2.

The substrate 100 may include a transparent material or an opaque material. In an embodiment, the substrate 100 may include glass, quartz, silicon, plastic, or the like. Examples of plastics, which may be included in the substrate 100, include polyimide (PI), polyethylene terephthalate (PET), polyethylene naphthalene (PEN), polypropylene (PP), polycarbonate (PC), polystyrene (PS), polysulfone (Psul), polyethylene (PE), polyphthalamide (PPA), polyethersulfone (PES), polyarylate (PAR), polycarbonate oxide (PCO), modified polyphenylene oxide (MPPO), and/or the like. These can be used alone or in combination with each other.

The buffer layer BF may be disposed on the substrate 100. The buffer layer BF may prevent or reduce impurities, such as oxygen and moisture from diffusing to an upper portion of the substrate 100 through the substrate 100, and may planarize an upper surface of the substrate 100. In an embodiment, the buffer layer BF may include an inorganic insulating material, such as a silicon compound, a metal oxide, or the like. Examples of the inorganic insulating material, which may be included in the buffer layer BF, include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), and/or the like. These can be used alone or in combination with each other. The buffer layer BF may have a single-layer structure or a multi-layer structure including a plurality of insulating layers. In an embodiment, the buffer layer BF may be omitted.

The active pattern ACT may be disposed on the buffer layer BF. For example, the active pattern ACT may include a silicon semiconductor, such as amorphous silicon, polycrystalline silicon, or the like. According to some embodiments, the active pattern ACT may include a metal oxide semiconductor. The active pattern ACT may have a source region, a drain region, and a channel region located between the source region and the drain region.

The first insulating layer IL1 may be disposed on the buffer layer BF. For example, the first insulating layer IL1 may cover the active pattern ACT and may be disposed along a profile of the active pattern ACT with a uniform thickness. The first insulating layer IL1 may insulate (e.g., electrically insulate) the channel region of the active pattern ACT from a gate electrode GAT disposed on the first insulating layer IL1. For example, the first insulating layer IL1 may include an inorganic insulating material, such as silicon oxide (SiOₓ), silicon nitride (SiNₓ), and/or the like. These can be used alone or in combination with each other.

The gate electrode GAT may be disposed on the first insulating layer IL1. In a plan view, the gate electrode GAT may overlap with the channel region of the active pattern ACT. For example, the gate electrode GAT may overlap with the channel region of the active pattern ACT in the third direction DR3. In an embodiment, the gate electrode GAT may include a conductive material, such as a metal, a metal alloy, a conductive metal nitride, a conductive metal oxide, a transparent conductive material, or the like. For example, the gate electrode GAT may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide ITO, tin oxide (SnOₓ), indium oxide (InOₓ), gallium oxide (GaOₓ), indium zinc oxide IZO, and/or the like. These can be used alone or in combination with each other.

The second insulating layer IL2 may be disposed on the first insulating layer IL1. The second insulating layer IL2 may cover the gate electrode GAT and may be disposed along a profile of the gate electrode GAT with a uniform thickness. For example, the second insulating layer IL2 may include an inorganic insulating material, such as silicon oxide (SiOₓ), silicon nitride (SiNₓ), and/or the like. These can be used alone or in combination with each other.

The source electrode SE and the drain electrode DE may be disposed on the second insulating layer IL2. The source electrode SE may be connected to the source region of the active pattern ACT through a contact hole penetrating the first insulating layer IL1 and the second insulating layer IL2. The drain electrode DE may be connected to the drain region of the active pattern ACT through a contact hole penetrating the first insulating layer IL1 and the second insulating layer IL2. For example, each of the source electrode SE and the drain electrode DE may include a conductive material, such as aluminum (Al), nickel (Ni), titanium (Ti), and/or the like. These can be used alone or in combination with each other.

Accordingly, the transistor TR including the source electrode SE, the drain electrode DE, the active pattern ACT, and the gate electrode GAT may be disposed in the display area DA.

The third insulating layer IL3 may be disposed on the second insulating layer IL2. The third insulating layer IL3 may substantially cover the source electrode SE and the drain electrode DE. In an embodiment, the third insulating layer IL3 may include an organic insulating material. Examples of the organic insulating material may include a photoresist, a polyacryl-based resin, a polyimide-based resin, a polyamide-based resin, a siloxane-based resin, an acryl-based resin, an epoxy-based resin, and/or the like. These can be used alone or in combination with each other. For example, the third insulating layer IL3 may have a single-layer structure or a multi-layer structure including a plurality of insulating layers.

The first electrode E1 may be disposed on the third insulating layer IL3. The first electrode E1 may be connected to the drain electrode DE through a contact hole penetrating the third insulating layer IL3. Accordingly, the first electrode E1 may be electrically connected to the transistor TR. For example, the first electrode E1 may include a conductive material, such as aluminum (Al), nickel (Ni), titanium (Ti), and/or the like. These can be used alone or in combination with each other. In an embodiment, the first electrode E1 may function as an anode.

The pixel defining layer PDL may be disposed on the third insulating layer IL3. The pixel defining layer PDL may cover an edge of the first electrode E1 and may define a pixel opening POP exposing a central portion of the first electrode E1. For example, the pixel defining layer PDL may include an organic insulating material, such as polyimide (PI), polyamide (PA), polystyrene (PS), polyvinyl alcohol (PVA), polyvinyl phenol (PVP), polymethyl methacrylate (PMMA), photoresist, acryl resin, epoxy resin, and/or the like. These can be used alone or in combination with each other.

In an embodiment, the pixel defining layer PDL may have a spacer portion SPC (e.g., a protrusion) protruding upward (e.g., in the third direction DR3) at an outer side of the first electrode E1, and a recessed portion REC (e.g., a recess) recessed downward (e.g., in a direction opposite to the third direction DR3) between the spacer portion SPC and the first electrode E1.

The spacer portion SPC of the pixel defining layer PDL may be disposed in the non-light-emitting area NEA. In an embodiment, the spacer portion SPC of the pixel defining layer PDL may have a quadrilateral cross-sectional shape having a taper angle with respect to the substrate 100. That is, a side surface of the spacer portion SPC may have an inclined profile. However, embodiments of the present disclosure are not limited thereto. For example, the side surface of the spacer portion SPC may have a vertical profile. The spacer portion SPC may support a fine metal mask.

The recessed portion REC of the pixel defining layer PDL may be disposed in the non-light-emitting area NEA. For example, the recessed portion REC of the pixel defining layer PDL may have a concave shape. Specifically, the recessed portion REC may have a concave shape that includes a curved concave surface.

In a comparative embodiment in which a pixel defining layer does not have a recessed portion, a second electrode may not be connected to a tip of a metal layer during deposition. Specifically, in case that the recessed portion is absent, the tip defining an undercut shape together with a pixel opening may have a linear shape. In case that the tip has the linear shape, the second electrode may not be deposited below the tip along the pixel opening. Accordingly, a problem in which the second electrode is disconnected may occur in the comparative embodiment.

In embodiments of the present disclosure in which the pixel defining layer PDL has the recessed portion REC, a deposition distance of the second electrode E2 along the pixel opening POP to the tip TP becomes shorter, so that the second electrode E2 and the metal layer MTL may be easily connected. As a result, the recessed portion REC of the pixel defining layer PDL may prevent or reduce the second electrode E2 from being disconnected.

The metal layer MTL may be disposed on the pixel defining layer PDL. The metal layer MTL may be disposed in the non-light-emitting area NEA. For example, the metal layer MTL may include a conductive material, such as a metal, a metal alloy, a conductive metal nitride, a conductive metal oxide, a transparent conductive material, or the like. In an embodiment, the metal layer MTL may have a single-layer structure including titanium. However, embodiments of the present disclosure are not limited thereto. In an embodiment, the metal layer MTL may have a multi-layer structure including titanium and aluminum.

In an embodiment, the metal layer MTL may have the tip TP defining the undercut shape (or recess) together with the pixel opening POP. Specifically, the tip TP may extend upward along the recessed portion REC and then extend substantially horizontally toward the pixel opening POP, without being bent downward along the pixel opening POP. The tip TP of the metal layer MTL may overlap with the light-emitting layer EL in a plan view. For example, the tip TP of the metal layer MTL may overlap with the light-emitting layer EL (including the pixel opening POP) in the third direction DR3. Additionally, the tip TP may be spaced apart from the light-emitting layer EL in the third direction DR3. Specifically, the first light-emitting area EA1 may be defined by an end portion of the tip TP in a plan view.

The tip TP may limit deposition of the light-emitting layer EL. Specifically, in case that an incident angle of equipment for depositing the light-emitting layer EL is fixed, a deposition area of the light-emitting layer EL may vary depending on a size of the opening OP defined by the tip TP. For example, as the size of the opening OP decreases, the deposition area of the light-emitting layer EL decreases, and accordingly, an area of the first light-emitting area EA1 may also decrease. In addition, as the size of the opening OP increases, the deposition area of the light-emitting layer EL increases, and accordingly, the area of the first light-emitting area EA1 may also increase. Therefore, by adjusting the size of the opening OP with the tip TP, the deposition area of the light-emitting layer EL and the area of the first light-emitting area EA1 may be optimized.

In an embodiment, an upper portion of the spacer portion SPC of the pixel defining layer PDL may be exposed from the metal layer MTL. In a comparative embodiment in which an upper portion of a spacer portion is not exposed, a fine metal mask for depositing a light-emitting layer may directly contact a metal layer on the upper portion of the spacer portion, which may cause arcing defects generated by charge concentration. As a result, by exposing the upper portion of the spacer portion SPC, arcing defects may be reduced or minimized, thereby improving reliability of the display device DD.

In an embodiment, a thickness of the metal layer MTL may be less than about 1000 Å. In a comparative embodiment in which the thickness of a metal layer is 1000 Å or greater, the metal layer may not be formed with a uniform thickness along the inclined profile of a spacer portion. Specifically, in case that sputtering the metal layer with the thickness of 1000 Å or greater, columnar growth in which the metal layer is abnormally thickly formed on the upper portion of the spacer portion may occur. As a result, in an etching process for exposing the upper portion of the spacer portion, residues of the metal layer may remain so that the upper portion of the spacer portion is not exposed, thereby causing arcing defects in the comparative embodiment.

The light-emitting layer EL may be disposed on the first electrode E1. The light-emitting layer EL may include a light-emitting material layer which emits at least one from among red light, green light, and blue light. For example, the light-emitting layer EL overlapping with the first light-emitting area EA1 in a plan view may include a light-emitting material layer which emits red light, the light-emitting layer EL overlapping with the second light-emitting area EA2 (see FIG. 2) in a plan view may include a light-emitting material layer which emits green light, and the light-emitting layer EL overlapping with the third light-emitting area EA3 (see FIG. 2) in a plan view may include a light-emitting material layer which emits blue light.

In an embodiment, the light-emitting layer EL may be disposed in the pixel opening POP. The light-emitting layer EL may include a first intermediate layer, the light-emitting material layer, and a second intermediate layer. The first intermediate layer may be disposed between the first electrode E1 and the light-emitting material layer, the light-emitting material layer may be disposed between the first intermediate layer and the second intermediate layer, and the second intermediate layer may be disposed between the light-emitting material layer and the second electrode E2. For example, the first intermediate layer may include a hole injection layer and a hole transport layer, and the second intermediate layer may include an electron transport layer and an electron injection layer.

The first dummy layer DM1 may be disposed on the metal layer MTL and the pixel defining layer PDL. In an embodiment, the first dummy layer DM1 may include the same material as a material of the light-emitting layer EL. That is, the first dummy layer DM1 may be formed through the same process as the light-emitting layer EL. In an embodiment, the first dummy layer DM1 may be disposed spaced apart from the light-emitting layer EL. The first dummy layer DM1 may be formed such that the light-emitting layer EL is separated from the first dummy layer DM1 by the tip TP. As a result, the tip TP may perform the same function as a separator which separates the light-emitting layer EL from the first dummy layer DM1. Accordingly, even if current is supplied to the light-emitting layer EL, current may not be supplied to an adjacent light-emitting layer (e.g., a light-emitting layer of the second light-emitting area EA2). As a result, leakage current may be reduced, and color purity of the display device DD may be improved.

The second electrode E2 may be disposed on the light-emitting layer EL. In an embodiment, the second electrode E2 may be connected to the tip TP of the metal layer MTL in the pixel opening POP. Accordingly, the second electrode E2 may be electrically connected to the metal layer MTL. That is, the metal layer MTL may serve as an auxiliary electrode for connecting adjacent second electrodes E2. Therefore, the second electrode E2 may have an effect of continuously extending across the light-emitting areas EA and the non-light-emitting area NEA. In an embodiment, the second electrode E2 may function as a cathode. A common voltage (ELVSS) may be applied to the second electrode E2.

For example, the second electrode E2 may include a conductive material. In an embodiment, the second electrode E2 may include a transparent conductive material (TCO), such as ITO, IZO, ZnO, ITZO, and/or the like, which can transmit light, and/or a semi-transmissive conductive material, such as an alloy of magnesium Mg and silver Ag. However, embodiments of the present disclosure are not limited thereto.

Accordingly, the light-emitting element LED including the first electrode E1, the light-emitting layer EL, and the second electrode E2 may be disposed in the first light-emitting area EA1.

The second dummy layer DM2 may be disposed on the first dummy layer DM1. In an embodiment, the second dummy layer DM2 may include the same material as a material of the second electrode E2. That is, the second dummy layer DM2 may be formed through the same process as the second electrode E2. In an embodiment, the second dummy layer DM2 may be disposed spaced apart from the second electrode E2. Specifically, the second dummy layer DM2 may be formed such that the second electrode E2 is separated from the second dummy layer DM2 by the tip TP.

The encapsulation layer ENC may be disposed on the second dummy layer DM2. The encapsulation layer ENC may prevent or reduce impurities, moisture, or the like from penetrating into the light-emitting element LED from the outside. The encapsulation layer ENC may include at least one inorganic layer and at least one organic layer. For example, the inorganic layer may include silicon oxide (SiOₓ), silicon nitride (SiNₓ), silicon oxynitride (SiOₓN_{y}), and/or the like. These can be used alone or in combination with each other. The organic layer may include a polymer cured material, such as polyacrylate, or the like.

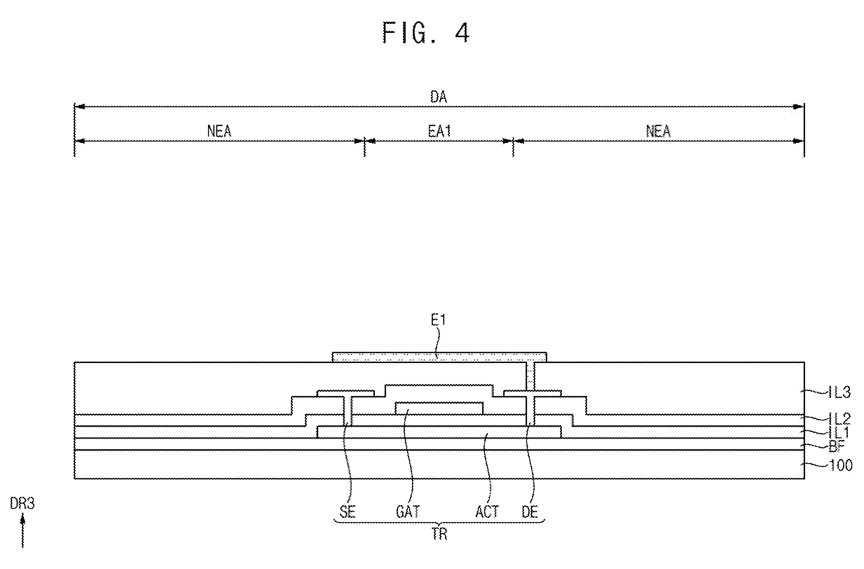

FIGS. 4-15 are cross-sectional views for illustrating a method of manufacturing the display device of FIG. 3.

Referring to FIG. 4, the buffer layer BF, the active pattern ACT, the first insulating layer IL1, the gate electrode GAT, the second insulating layer IL2, the source electrode SE, the drain electrode DE, the third insulating layer IL3, and the first electrode E1 may be sequentially formed on the substrate 100.

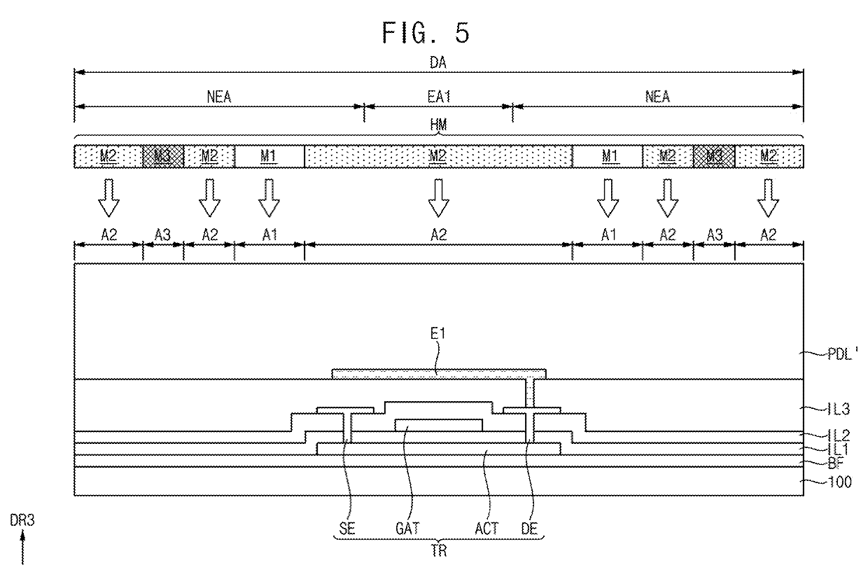

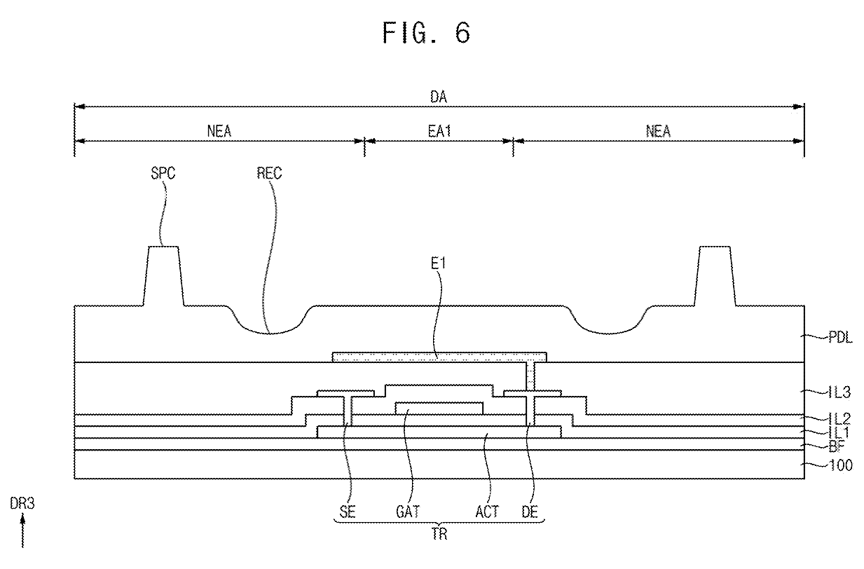

Referring to FIGS. 5 and 6, a preliminary pixel defining layer PDL’ may be formed on the first electrode E1 and the third insulating layer IL3. For example, the preliminary pixel defining layer PDL’ may be formed with an organic insulating material, such as polyimide (PI), polyamide (PA), polystyrene (PS), and/or the like.

A mask having a pattern may be used to pattern the preliminary pixel defining layer PDL’. In an embodiment, the mask may include a half-tone mask HM including a first semi-transmissive portion M1, a second semi-transmissive portion M2, and a light-shielding portion M3. In this embodiment, the preliminary pixel defining layer PDL’ is described as a positive type in which an exposed portion is removed. However, embodiments of the present disclosure are not limited thereto. For example, the preliminary pixel defining layer PDL’ may also be a negative type.

After aligning the half-tone mask HM on the preliminary pixel defining layer PDL’ and performing an exposure process by irradiating light, a development process for removing an exposed portion may be performed. At this time, a first region A1 of the preliminary pixel defining layer PDL’ corresponding to (e.g., overlapping with) the first semi-transmissive portion M1 of the half-tone mask HM may have a greater light transmittance than a second region A2 of the preliminary pixel defining layer PDL’ corresponding to (e.g., overlapping with) the second semi-transmissive portion M2, and a third region A3 of the preliminary pixel defining layer PDL’ corresponding to (e.g., overlapping with) the light-shielding portion M3 may not transmit light. Specifically, the first region A1 of the preliminary pixel defining layer PDL’ corresponding to the first semi-transmissive portion M1 may correspond to the recessed portion REC described below, and the third region A3 of the preliminary pixel defining layer PDL’ corresponding to the light-shielding portion M3 may correspond to the spacer portion SPC described below. Accordingly, the pixel defining layer PDL having the spacer portion SPC protruding upward at the outer side of the first electrode E1, and the recessed portion REC recessed downward between the spacer portion SPC and the first electrode E1, may be formed. The spacer portion SPC of the pixel defining layer PDL may be configured as a spacer, thereby an additional process for forming an additional spacer may be omitted. Therefore, the manufacturing process may be simplified, productivity may be improved, and process costs may be reduced.

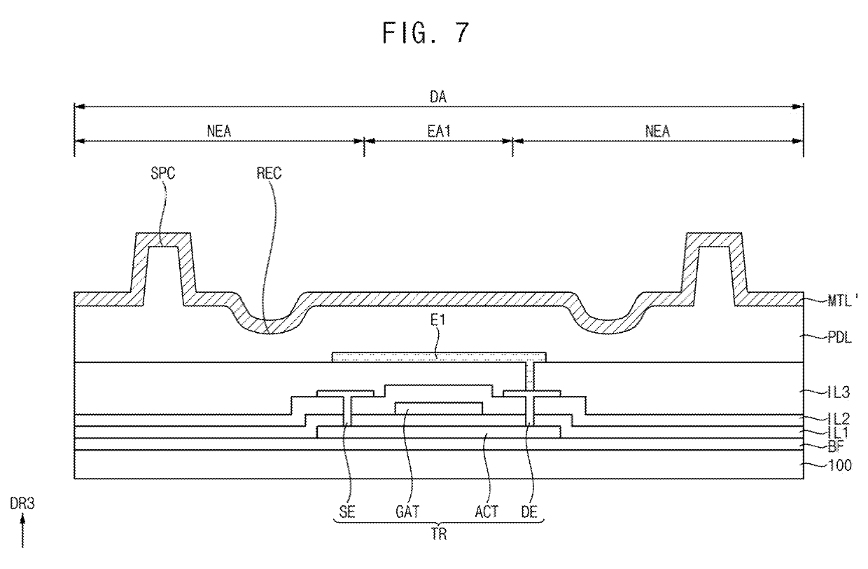

Referring to FIG. 7, a preliminary metal layer MTL’ may be formed on the pixel defining layer PDL. In an embodiment, the preliminary metal layer MTL’ may be formed with a thickness less than about 1000 Å. The preliminary metal layer MTL’ may be formed by a sputtering process. In an embodiment, the preliminary metal layer MTL’ may be formed using titanium (Ti), aluminum (Al), and/or the like.

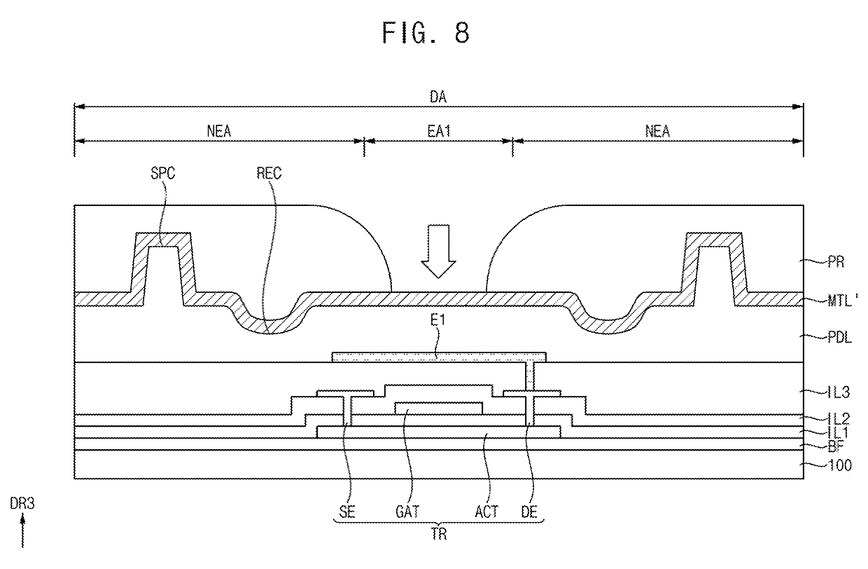

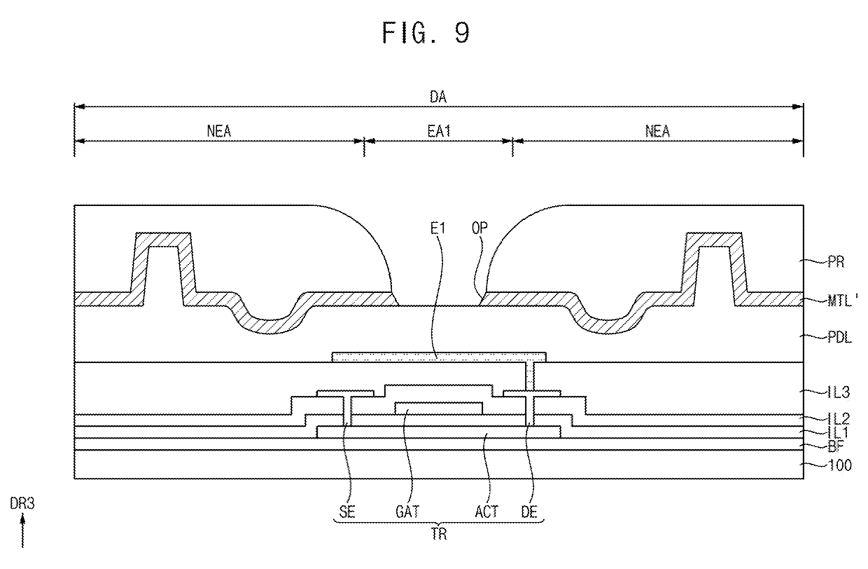

Referring to FIGS. 8 and 9, a photoresist pattern PR may be formed on the preliminary metal layer MTL’. By using the photoresist pattern PR as a mask for an etching process, a portion of the preliminary metal layer MTL’ exposed by the photoresist pattern PR may be removed. As a result, the opening OP overlapping with the first electrode E1 in a plan view (e.g., overlapping in the third direction DR3) and exposing an upper surface of the pixel defining layer PDL may be formed in the preliminary metal layer MTL’. For example, the etching process may be a dry etching method, a wet etching method, a reactive ion etching (RIE), a deep reactive ion etching (DRIE), an inductively coupled plasma reactive ion etching (ICP-RIE), or the like. In an embodiment, the etching process may be the dry etching method. However, embodiments of the present disclosure are not limited thereto.

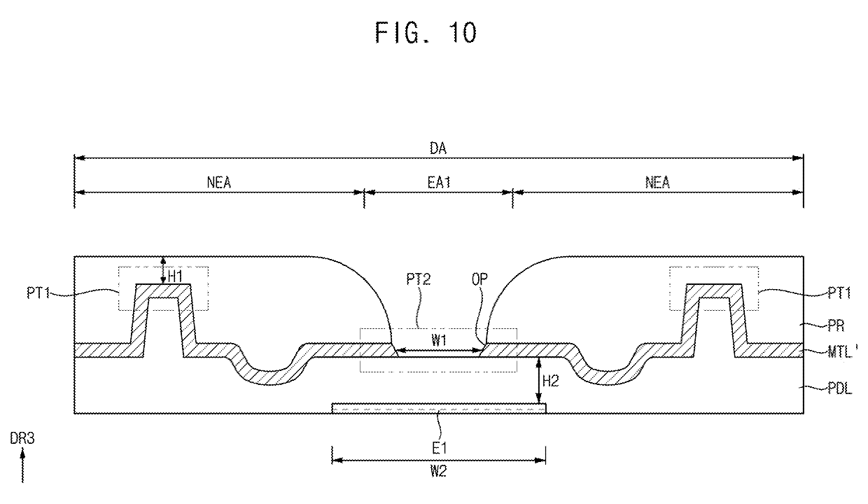

Referring to FIG. 10, the preliminary metal layer MTL’ may include a first portion PT1 and a second portion PT2. The first portion PT1 of the preliminary metal layer MTL’ may be a portion contacting the upper portion of the spacer portion SPC. The second portion PT2 of the preliminary metal layer MTL’ may be a portion adjacent to the opening OP.

In an embodiment, a height H1 from an upper surface of the first portion PT1 of the preliminary metal layer MTL’ to an upper surface of the photoresist pattern PR may be less than a height H2 from an upper surface of the first electrode E1 to an upper surface of the pixel defining layer PDL. In case that this condition is satisfied, after performing overall ashing in a subsequent process, the first portion PT1 of the preliminary metal layer MTL’ may be exposed. As a result, by performing an etching process on the exposed preliminary metal layer MTL’ and removing the first portion PT1 of the preliminary metal layer MTL’, arcing defects may be reduced or minimized.

In an embodiment, a first width W1 of the opening OP at the second portion PT2 of the preliminary metal layer MTL’ may be less than a second width W2 of the first electrode E1. After performing the overall ashing in the subsequent process, the second portion PT2 of the preliminary metal layer MTL’ may be exposed and may be removed in the etching process. Therefore, in a case that this condition is not satisfied in a comparative embodiment, a tip of a metal layer may not be properly formed.

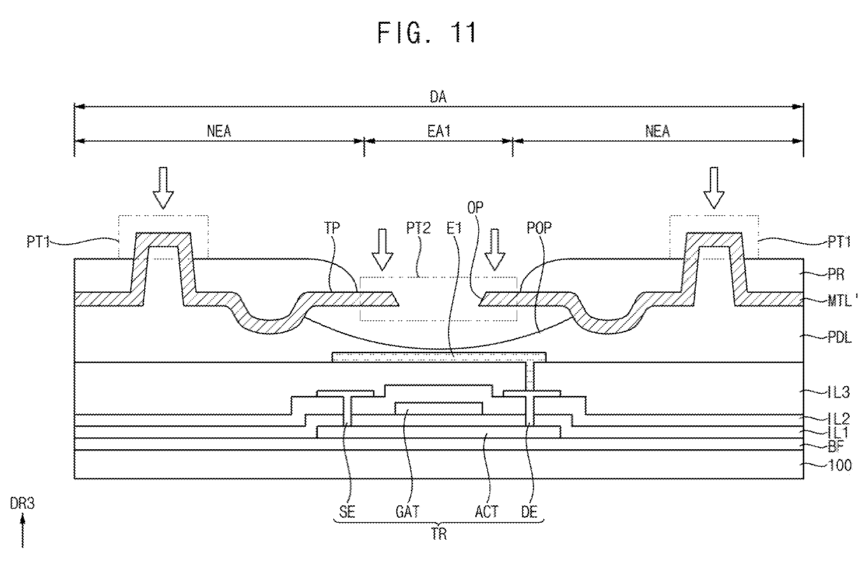

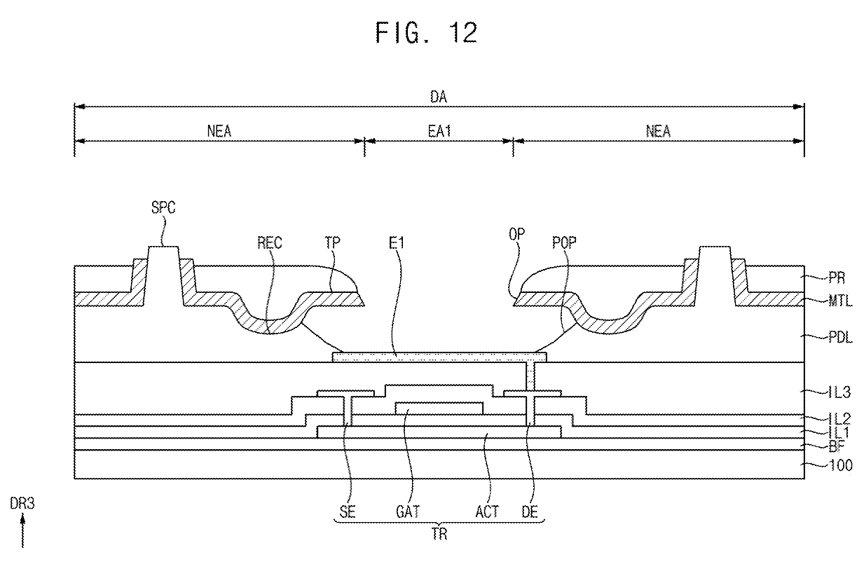

Referring to FIGS. 11 and 12, in an embodiment, overall ashing may be performed in the display area DA in order to remove a portion of the photoresist pattern PR and a portion of the pixel defining layer PDL. Specifically, through the overall ashing, the portion of the photoresist pattern PR may be removed so that the first portion PT1 of the preliminary metal layer MTL’ contacting the upper portion of the spacer portion SPC may be exposed. In addition, through the overall ashing, the portion of the photoresist pattern PR may be removed so that an upper surface of the second portion PT2 of the preliminary metal layer MTL’ adjacent to the opening OP may be exposed. At the same time, the portion of the pixel defining layer PDL may be removed so that the pixel opening POP may be formed. As a result, the preliminary metal layer MTL’ may have the tip TP including the second portion PT2 and defining the opening OP, and the undercut shape may be defined by the pixel opening POP and the tip TP. In the configuration shown in FIG. 11, the tip TP may also be referred to as a preliminary tip. In an embodiment, in a case where the portion of the pixel defining layer PDL is removed to form the pixel opening POP, the tip TP may extend from the end portion of the second portion PT2 adjacent to the opening OP to a portion of the preliminary metal layer MTL’ that bends downward toward the recessed portion REC.

In a case where the pixel opening POP is formed by removing the portion of the pixel defining layer PDL through the overall ashing, the first electrode E1 may not be exposed. In an embodiment, in a case of etching the first portion PT1 and the second portion PT2 of the exposed preliminary metal layer MTL’, a portion of the photoresist pattern PR and a portion of the pixel defining layer PDL may be removed, and a size of the pixel opening POP may be expanded. As a result, the central portion of the first electrode E1 may be exposed. However, embodiments of the present disclosure are not limited thereto. For example, in a case where the pixel opening POP is formed by removing the portion of the pixel defining layer PDL through the overall ashing, the central portion of the first electrode E1 may be exposed.

In an embodiment, through the etching process using the photoresist pattern PR as a mask, the first portion PT1 and the second portion PT2 of the preliminary metal layer MTL’ exposed by the photoresist pattern PR may be removed. As a result, the upper portion of the spacer portion SPC of the pixel defining layer PDL may be exposed, and a length of the tip TP may become shorter. As a result, the metal layer MTL having a tip TP defining the undercut shape together with the pixel opening POP and exposing the upper portion of the spacer portion SPC may be formed. For example, the etching process may be a dry etching method, a wet etching method, a reactive ion etching method, a deep reactive ion etching method, an inductively coupled plasma reactive ion etching method, or the like. In an embodiment, the etching process may be the dry etching method. However, embodiments of the present disclosure are not limited thereto.

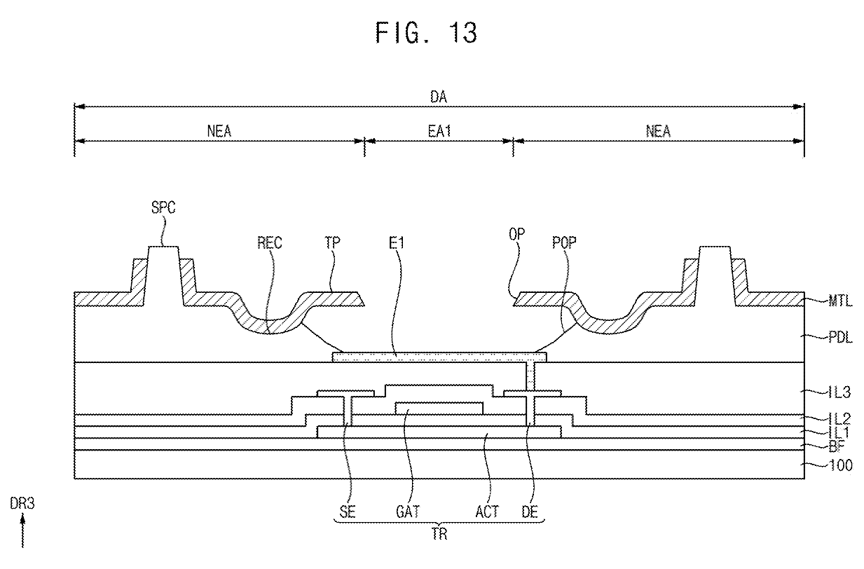

Referring to FIG. 13, the photoresist pattern PR may be removed. For example, the photoresist pattern PR may be removed through a strip process or an ashing process.

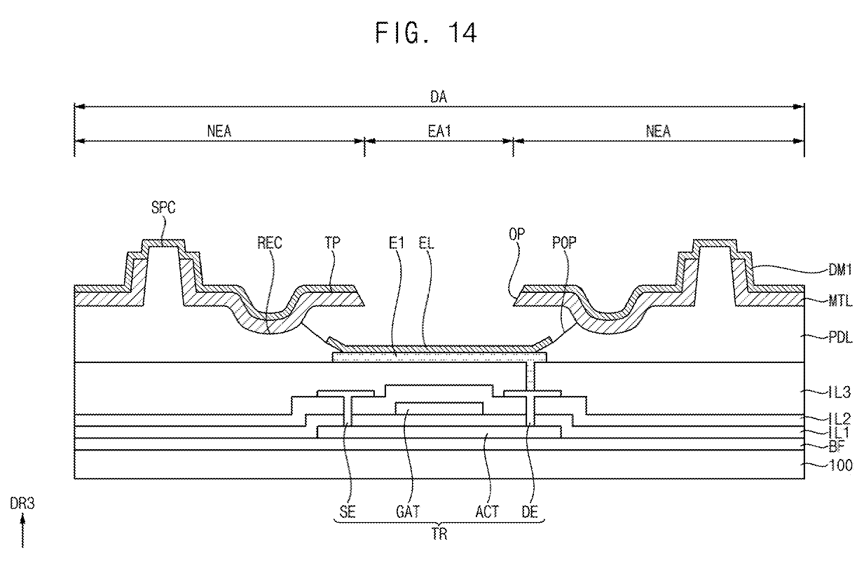

Referring to FIG. 14, the light-emitting layer EL may be formed on the first electrode E1. The light-emitting layer EL may be formed using a light-emitting material which emits light of a selected color. In an embodiment, the light-emitting layer EL may be formed by deposition being limited by the tip TP of the metal layer MTL. Specifically, in a case where the incident angle of equipment for depositing the light-emitting layer EL is fixed, the deposition area of the light-emitting layer EL may be differently formed depending on the size of the opening OP defined by the tip TP. For example, as the size of the opening OP decreases, the deposition area of the light-emitting layer EL decreases, and accordingly, the area of the first light-emitting area EA1 may also decrease.

The first dummy layer DM1 may be formed on the metal layer MTL. In an embodiment, the first dummy layer DM1 may be formed using the same material as a material of the light-emitting layer EL. That is, the first dummy layer DM1 may be simultaneously formed through the same process as the light-emitting layer EL.

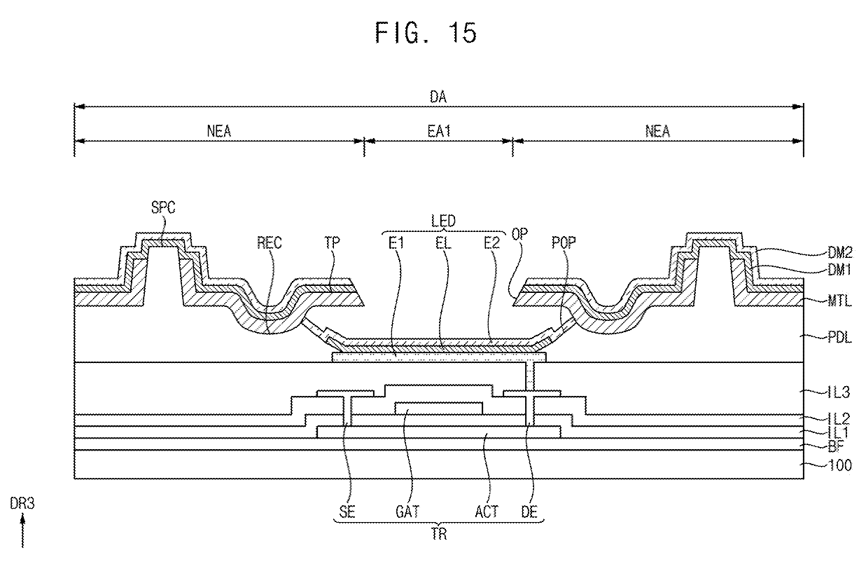

Referring to FIG. 15, the second electrode E2 may be formed on the light-emitting layer EL. For example, the second electrode E2 may be formed with a conductive material. In an embodiment, the second electrode E2 may be formed with a transparent conductive material (TCO), such as ITO, IZO, ZnO, ITZO, and/or the like, which can transmit light, and/or a semi-transmissive conductive material, such as an alloy of magnesium (Mg) and silver (Ag).

In an embodiment, the second electrode E2 may be formed to be connected to the tip TP of the metal layer MTL in the pixel opening POP. In an embodiment, the second electrode E2 may be formed in the pixel opening POP by a sputtering process without being restricted by the incident angle.

The second dummy layer DM2 may be formed on the first dummy layer DM1. In an embodiment, the second dummy layer DM2 may be formed using the same material as a material of the second electrode E2. That is, the second dummy layer DM2 may be simultaneously formed through the same process as the second electrode E2.

Accordingly, the light-emitting element LED including the first electrode E1, the light-emitting layer EL, and the second electrode E2 may be formed in the first light-emitting area EA1.

Referring again to FIG. 3, the encapsulation layer ENC may be formed on the second electrode E2 and the second dummy layer DM2. The encapsulation layer ENC may include at least one inorganic layer and at least one organic layer.

Accordingly, the display device DD illustrated in FIG. 3 may be manufactured.

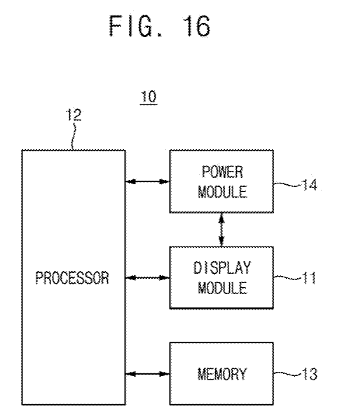

The display device DD according to embodiments of the present disclosure may be applied to various electronic devices. An electronic device 10 (see FIG. 16) according to an embodiment may include the display device DD described above, and may further include a module or device having additional functions in addition to the display device DD.

FIG. 16 is a schematic block diagram of an electronic device according to an embodiment of the present disclosure.

Referring to FIG. 16, the electronic device 10 according to an embodiment may include a display module 11, at least one processor 12, a memory 13, and a power module 14.

The at least one processor 12 may control the display device. The at least one processor 12 may include at least one from among a central processing unit (CPU), an application processor (AP), a graphic processing unit (GPU), a communication processor (CP), an image signal processor (ISP), and a controller.

Data information for the operation of the at least one processor 12 or the display module 11 may be stored in the memory 13. In a case where the at least one processor 12 executes an application stored in the memory 13, an image data signal and/or an input control signal is transmitted to the display module 11, and the display module 11 may process the received signal and output image information through a display screen.

The power module 14 may include a power supply module (e.g., a power supply) such as a power adapter or a battery device, and a power conversion module (e.g., a power converter) which converts power supplied by the power supply module to generate power for the operation of the electronic device 10.

At least one of the components of the electronic device 10 described above may be included in a display device (e.g., the display device DD of FIG. 1) according to the embodiments described above. Some of the individual modules functionally included in a single module may be included in the display device, while others may be provided separately from the display device. For example, the display device may include the display module 11, and the at least one processor 12, the memory 13, and the power module 14 may be provided in the form of other devices in the electronic device 10 other than the display device.

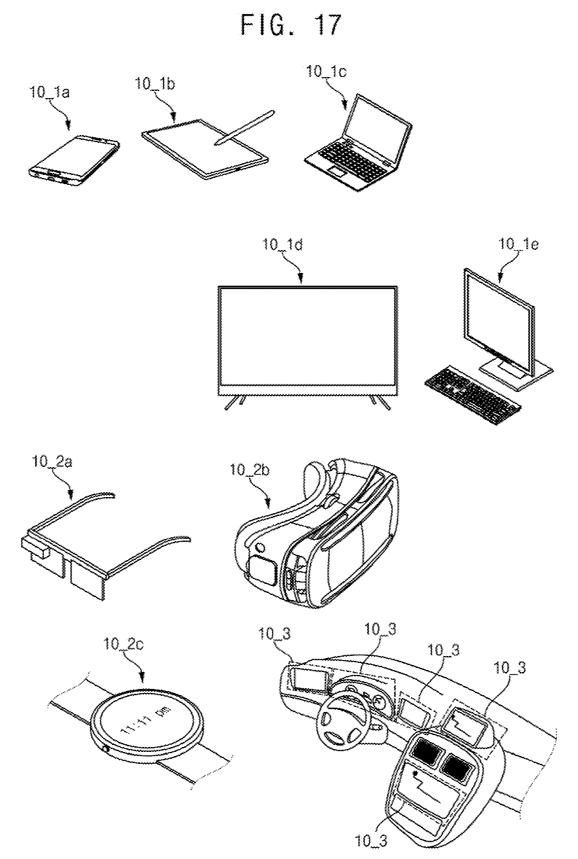

FIG. 17 is a schematic diagram of various electronic devices according to various embodiments.

Referring to FIG. 17, various electronic devices to which display devices according to embodiments (e.g., display device DD of FIG. 1) are applied may include not only image display electronic devices (e.g., a smart phone 10_1b, a tablet 10_1b, a laptop 10_1c, a TV 10_1d, and a desk monitor 10_1e), but also wearable electronic devices including display module (e.g., smart glasses 10_2a, a head mounted display 10_2b, and a smart watch 10_2c), and vehicle electronic devices 10_3 including display modules (e.g., a center information display (CID) and a room mirror display arranged on an instrument panel, a center fascia, and a dashboard of an automobile).

According to some embodiments of the present disclosure, a display device and an electronic device including the same may be provided. For example, embodiments of the present disclosure may be applied to high-resolution smart phones, mobile phones, smart pads, smart watches, tablets, vehicle navigation systems, televisions, computer monitors, laptops, or the like.

Although non-limiting example embodiments of the present disclosure have been described above with reference to the accompanying drawings, it will be understood by those skilled in the art that various modifications and changes may be made therein without departing from the spirit and scope of the present disclosure.

What is claimed is:

1. A display device comprising:
a substrate;
a first electrode on the substrate;
a pixel defining layer on the first electrode and comprising:
a pixel opening exposing a central portion of the first electrode,
a spacer portion at an outer side of the first electrode, the spacer portion protruding in an upward direction; and
a recessed portion between the spacer portion and the pixel opening, the recessed portion being recessed in a downward direction;
a metal layer on the pixel defining layer and comprising a tip, the tip overlapping with the pixel opening in the upward direction, and defining a light-emitting area;
a light-emitting layer on the first electrode; and
a second electrode on the light-emitting layer, in the pixel opening, wherein the second electrode is connected to the tip of the metal layer.

2. The display device of claim 1, wherein the tip overlaps with the light-emitting layer in the upward direction.

3. The display device of claim 1, wherein an upper portion of the spacer portion is exposed from the metal layer.

4. The display device of claim 1, wherein a thickness of the metal layer is less than 1000 Å.

5. The display device of claim 1, wherein the metal layer comprises only a single layer, the single layer comprising titanium.

6. The display device of claim 1, wherein the metal layer comprises a first layer comprising titanium, and a second layer comprising aluminum.

7. The display device of claim 1, further comprising:
a first dummy layer on the pixel defining layer, wherein a material of the first dummy layer is the same as a material of the light-emitting layer; and
a second dummy layer on the first dummy layer, wherein a material of the second dummy layer is the same as a material of the second electrode.

8. The display device of claim 7, wherein the first dummy layer is spaced apart from the light-emitting layer.

9. The display device of claim 7, wherein the second dummy layer is spaced apart from the second electrode.

10. A method of manufacturing a display device, the method comprising:
forming a first electrode on a substrate;
forming a pixel defining layer on the first electrode, the pixel defining layer including:
a spacer portion at an outer side of the first electrode, the spacer portion protruding in an upward direction; and
a recessed portion between the spacer portion and the first electrode, the recessed portion being recessed in a downward direction;
forming a preliminary metal layer on the pixel defining layer;
forming, by removing a portion of the pixel defining layer, a pixel opening that exposes a central portion of the first electrode;
forming a metal layer by removing a portion of the preliminary metal layer, wherein the metal layer includes a tip that overlaps with the pixel opening in the upward direction and defines a light-emitting area;
forming a light-emitting layer on the first electrode; and
forming a second electrode on the light-emitting layer, in the pixel opening, wherein the second electrode is connected to the tip of the metal layer.

11. The method of claim 10, wherein the forming the pixel defining layer comprises forming the pixel defining layer by using a halftone mask.

12. The method of claim 10, wherein the metal layer includes:
only a single layer, the single layer including titanium; or
a first layer including titanium, and a second layer including aluminum.

13. The method of claim 10, wherein the forming the metal layer comprises:
forming a photoresist pattern on the preliminary metal layer;
forming an opening, overlapping with the first electrode in the upward direction, by removing a portion of the preliminary metal layer exposed from the photoresist pattern;
exposing, by removing a portion of the photoresist pattern, a first portion of the preliminary metal layer in contact with the spacer portion and a second portion of the preliminary metal layer adjacent to the opening;
removing the first portion and the second portion of the preliminary metal layer; and
removing a remainder of the photoresist pattern, and
wherein the forming the pixel opening is performed simultaneously with the removing the portion of the photoresist pattern.

14. The method of claim 13, wherein, after the forming the pixel opening, the preliminary metal layer includes the second portion and a preliminary tip, the preliminary tip defining the opening.

15. The method of claim 13, wherein the removing the first portion and the second portion of the preliminary metal layer comprises expanding a size of the pixel opening so that at least a portion of the first electrode is exposed.

16. The method of claim 13, wherein, after the forming the photoresist pattern, a height from an upper surface of the first portion of the preliminary metal layer to an upper surface of the photoresist pattern is less than a height from an upper surface of the first electrode to an upper surface of the pixel defining layer.

17. The method of claim 13, wherein, after the forming the opening,
a width of the opening is less than a width of the first electrode.

18. An electronic device comprising:
the display device of claim 1; and
at least one processor configured to control the display device.

19. The electronic device of claim 18, wherein an upper portion of the spacer portion is exposed from the metal layer, and the tip overlaps with the light-emitting layer in the upward direction.

20. The electronic device of claim 18, wherein a thickness of the metal layer is less than about 1000 Å.
